(19) United States
(12) Patent Application Publication
(10) Pub. No.: US 2018/0130702 A1
(43) Pub. Date: May 10, 2018

(54) ENCAPSULATION OF COBALT METALLIZATION

(71) Applicant: GLOBALFOUNDRIES Inc., Grand Cayman (KY)

(72) Inventors: Suraj K. Patil, Ballston Lake, NY (US); Viraj Sardesai, Malta, NY (US)

(21) Appl. No.: 15/345,858

(22) Filed: Nov. 8, 2016

(51) Int. Cl. H01L 21/768; H01L 23/522; H01L 23/532

(52) U.S. Cl. CPC H01L 21/76849; H01L 23/5226; H01L 21/76877; H01L 21/76802; H01L 21/76843; H01L 23/53209

(57) ABSTRACT

Structures that include cobalt metallization and methods of forming such structures. A feature is located inside an opening in a dielectric layer and a cap layer located on a top surface of the feature. The feature is composed of cobalt, and the cap layer is composed of ruthenium or a cobalt-containing alloy.

### BACKGROUND

The present invention relates to integrated circuits and semiconductor device fabrication and, more specifically, to structures that include cobalt metallization and methods of forming such structures.

An interconnect structure may be used to electrically connect device structures fabricated on a substrate by front-end-of-line (FEOL) processing. A back-end-of-line (BEOL) portion of the interconnect structure may be formed using a dual damascene process in which via openings and trenches etching in a dielectric layer are simultaneously filled with metal to create a metallization level. The lowest or first metal level of the BEOL interconnect structure may be coupled with the device structures by contacts formed prior to BEOL processing using a middle-of-line (MOL) processing.

The MOL contacts are formed in openings defined in a dielectric layer that covers the device structures. Cobalt is a material of interest for forming MOL contacts, and other metallization found in the MOL portion of the interconnect structure, as a replacement material for tungsten. While cobalt exhibits characteristics that make its use attractive, cobalt tends to be transported from the contacts to the surface of the dielectric layer following planarization by chemical mechanical polishing. The presence of cobalt on the top surface of the dielectric layer may cause leakage paths and/or electrical shorts, which may lead to device failure.

Improved structures that include cobalt metallization and methods of forming such structures are needed.

### SUMMARY

According to an embodiment of the invention, a structure includes a feature inside an opening in a dielectric layer and a cap layer located on a top surface of the feature. The opening that penetrates from the top surface of the dielectric layer into the dielectric layer. The feature is composed of cobalt, and the cap layer is composed of ruthenium or a cobalt-containing alloy.

According to another embodiment of the invention, a method includes forming an opening in a dielectric layer, forming a feature in the opening, and forming a cap layer on a top surface of the feature. The feature is composed of cobalt, and the cap layer is composed of ruthenium or a cobalt-containing alloy.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-3 are cross-sectional views of a structure at successive fabrication stages of a processing method in accordance with an embodiment of the invention.

### DETAILED DESCRIPTION

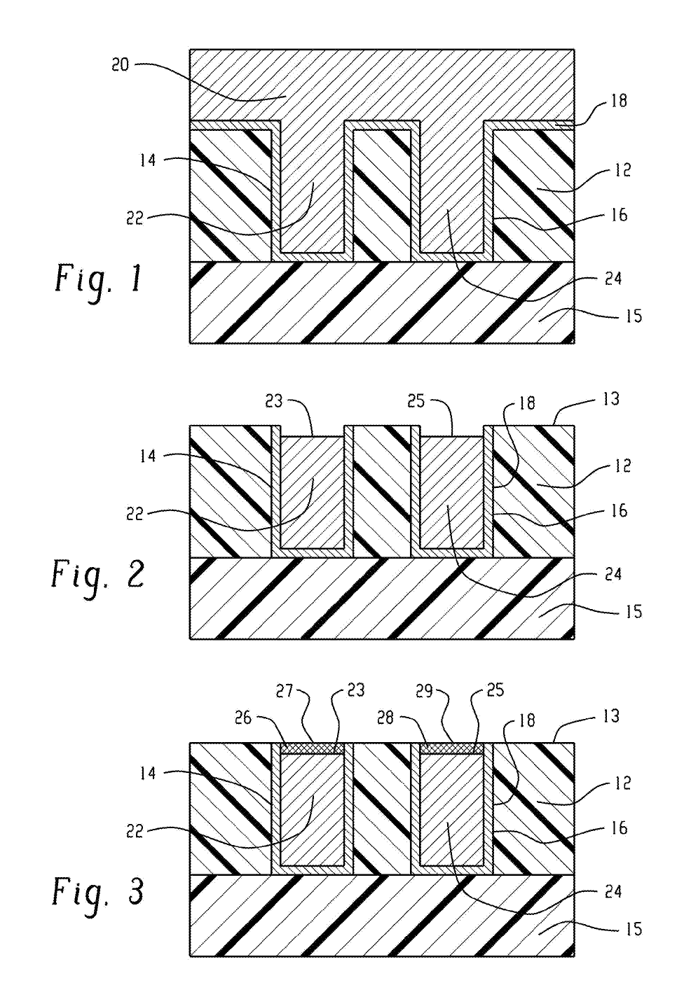

With reference to FIG. 1 and in accordance with an embodiment of the invention, a dielectric layer 12 may be processed by middle-of-line (MOL) processing or back-end-of-line (BEOL) to form a metallization level of an interconnect structure. The dielectric layer 12 may be composed of an electrical insulator, such as silicon dioxide deposited using tetraethylorthosilicate (TEOS) as a reactant gas, silicon nitride (Si₃N₄), or another suitable dielectric material.

Openings, of which openings 14, 16 are representative, may be formed by photolithography and etching at selected locations distributed across the surface area of dielectric layer 12. Specifically, a resist layer may be applied, exposed to a pattern of radiation projected through a photomask, and developed to form a corresponding pattern of openings situated at the intended locations for the openings. The patterned resist layer is used as an etch mask for a dry etching process, such as a reactive-ion etching (RIE), that removes portions of the dielectric layer 12 to form the openings 14, 16. The etching process may be conducted in a single etching step or multiple etching steps with different etch chemistries. The openings 14, 16 may have an aspect ratio characteristic of a contact opening or a trench.

The openings 14, 16 may be contact openings or trenches defined in the dielectric layer 12. The openings 14, 16 may open onto an underlying feature, which is generally indicated by reference numeral 15, of a device structure. The feature 15 of the device structure may be the source, drain, or gate of a transistor, or the base, emitter, or collector of a bipolar junction transistor, formed on a substrate. The openings 14 have respective sidewalls that extend from a top surface 13 of the dielectric layer 12 to the feature 15 of the device structure. Alternatively, the feature 15 of the device structure may be a conductive feature in an underlying dielectric layer that is aligned with one or both of the openings 14.

A barrier/liner layer 18 of a given thickness is deposited on the sidewalls and base of the openings 14, 16 and also in the field area on the top surface of the dielectric layer 12. The barrier/liner layer 18 may be comprised of titanium (Ti), titanium nitride (TiN), tantalum (Ta), tantalum nitride (TaN), or a multilayer combination of these materials (e.g., a TaN/Ta bilayer) deposited by physical vapor deposition (PVD) with, for example, a sputtering process. The barrier/liner layer 18 conforms to the shape of the openings 14, 16 such that the dielectric layer 12 bordering the openings 14, 16 is completely covered.

A cobalt layer 20 of a given thickness may be formed that overfills the openings 14, 16, and that is formed on the field area on the top surface of the dielectric layer 12. The cobalt layer 20 may be deposited by PVD or by CVD using a cobalt-containing precursor, such as a cobalt-containing carbonyl precursor, as a reactant.

With reference to FIG. 2 in which like reference numerals refer to like features in FIG. 1 and at a subsequent fabrication stage, the thickness of the cobalt layer 20 is reduced and portions of the cobalt layer 20 in the field area on the top surface of the dielectric layer 12 is removed by planarization, such as a chemical mechanical polishing (CMP) process. The barrier/liner layer 18 in the field area on the top surface of dielectric layer 12 is also removed by planarization, such as with a different chemical CMP process. Material removal during each CMP process may combine abrasion and an etching effect that polishes the targeted material. Each CMP process may be conducted with a commercial tool using standard a polishing pad and slurries selected to polish the targeted material.

Cobalt features 22, 24 are defined as the remaining portions of the cobalt layer 20 located inside the openings 14, 16 and that are embedded in the dielectric layer 12 after planarization. The top surface 23 of the cobalt feature 22, the top surface 25 of the cobalt feature 24, and the top surface 13 of the dielectric layer 12 adjacent to the top surfaces 23, 25 of the cobalt features 22, 24 are exposed following the planarization. The top surfaces 23, 25 may be convexly curved, concavely curved, or planar. In an embodiment, the top surfaces 23, 25 of the cobalt features 22, 24 may be recessed below the top surface 13 of the dielectric layer 12. For example, the CMP process may recess the top surfaces 23, 25. In another embodiment, the respective top surfaces 23, 25 of the cobalt features 22, 24 may be coplanar with the top surface 13 of the dielectric layer 12. In an embodiment, an etch back process may be used to recess the respective top surfaces 23, 25 of the cobalt features 22, 24. The barrier/liner layer 18 operates as a diffusion barrier to cobalt such that the cobalt cannot be transported from the cobalt features 22, 24 outwardly into the dielectric layer 12.

With reference to FIG. 3 in which like reference numerals refer to like features in FIG. 2 and at a subsequent fabrication stage, a cap layer 26 is formed on the top surface 23 of the cobalt feature 22 and a cap layer 28 is concurrently formed on the top surface 25 of the cobalt feature 24. The cap layer 26 has a lower surface that contacts and is coextensive with the top surface 23 of cobalt feature 22, and the cap layer 26 may cover the entire surface area of the top surface 23 of cobalt feature 22. The cap layer 26 cam be coextensive at its outer edge with the barrier/liner layer 18 inside opening 14. The cap layer 28 has a lower surface that contacts and is coextensive with the top surface 25 of cobalt feature 24, and the cap layer 28 may cover the entire surface area of the top surface 25 of cobalt feature 24. The cap layer 28 may be coextensive at its outer edge with the barrier/liner layer 18 inside opening 16. The cap layer 26 and barrier/liner layer 18 inside opening 14 may cooperate to encapsulate the cobalt feature 22 and the cap layer 28 and the barrier/liner layer 18 inside opening 16 may cooperate to encapsulate the cobalt feature 24 so that the cobalt features 22, 24 are enclosed and isolated inside the openings 14, 16 against outward transport of the cobalt and to prevent cobalt oxidation. The cap layers 26, 28 have respective upper surfaces 27, 29 that face away from the corresponding cobalt features 22, 24 and the lower surfaces that contact the surfaces 23, 25 of the cobalt features 22, 24.

The cap layers 26, 28 may be formed by selective deposition of conductive material on the surfaces 23, 25 of the cobalt features 22, 24 with atomic layer deposition (ALD) or CVD. To that end, a solid reaction product is selectively formed by nucleation on the surfaces 23, 25 to form the cap layers 26, 28, but the reaction product does not nucleate and form on the top surface 13 of the dielectric layer 12 adjacent to the cobalt features 22, 24. Deposition conditions may be selected to produce a thin film that is highly conductive (i.e., low electrical resistance) and that exhibits good adhesion to cobalt without depositing the conductive material on dielectric surfaces. The selective deposition promotes the coverage by the cap layers 26, 28 of the entire surface area of the top surfaces 23, 25 of cobalt features 22, 24. The selective deposition also eliminates the need for polishing with CMP or an etch back to remove material from the top surface 13 of the dielectric layer 12.

In an embodiment, the cap layers 26, 28 may be composed of a metal, such as ruthenium (Ru) formed using a volatile metal precursor of ruthenium deposited by low-temperature CVD or ALD. In alternative embodiments, the cap layers 26, 28 may be composed of cobalt and another metallic element, such as nickel (Ni), ruthenium (Ru), niobium (Nb), tantalum (Ta), or manganese (Mn), that is selectively formed using CVD or ALD. In an embodiment, the cap layers 26, 28 may have a bi-layer or multi-layer include two or more layers of different metallic alloys and/or single metals. In embodiments, the cap layers 26, 28 may be a binary alloy of these elements. In embodiments, the cap layers 26, 28 may each have a thickness on the order of 1 nanometer to 10 nanometers.

The cap layer 26 may occupy space inside opening 14 that is above the cobalt feature 22. Similarly, the cap layer 28 may occupy space inside opening 16 that is above the cobalt feature 24. If the top surfaces 23, 25 of the cobalt features 22, 24 are recessed within the openings 14, 16, the top surfaces 27, 29 of the cap layers 26, 28 may be coplanar with the adjacent top surface 13 of the dielectric layer 12. In an alternative embodiment, the top surfaces 27, 29 of the cap layers 26, 28 may be partially recessed relative to the adjacent top surface 13 of the dielectric layer 12. In an alternative embodiment, the top surfaces 27, 29 of the cap layers 26, 28 may project slightly above the adjacent top surface 13 of the dielectric layer 12. The distance over which the cobalt features 22, 24 are recessed, if recessed, and the thickness of the cap layers 26, 28 are factors that determine the relationship between the top surfaces 27, 29 of the cap layers 26, 28 and the adjacent top surface 13 of the dielectric layer 12.

The cap layers 26, 28 may prevent the transport or migration of cobalt from the cobalt features 22, 24 to other locations in the interconnect structure at the level of the top surface 13 of dielectric layer 12 or interlayer dielectric layer of an interconnect level formed above the interconnect level including the dielectric layer 12 and cobalt features 22, 24. The cap layers 26, 28 may operate as protection layers that improve the compatibility of the cobalt features 22, 24 with etching and cleaning processes used in damascene processes. Vertical openings formed by etching open onto the top surfaces 27, 29 of the cap layers 26, 28 instead of the top surfaces 23, 25 of the cobalt features 22, 24, which averts gouging of the underlying cobalt features 22, 24. The cap layers 26, 28 may function to prevent oxidation or reoxidation of the top surfaces 23, 25 of the cobalt features 22, 24. Oxidation of the cap layers 26, 28 forms an oxide of ruthenium, such as ruthenium oxide (RuOₓ), and may be tolerated because ruthenium oxide is a conductor and has a lower resistivity than an oxide of cobalt.

After the cap layers 26, 28 are formed, a thermal anneal may be performed to cause cobalt from the cobalt features 22, 24 to reflow into any microtrenches formed at corners inside the openings 14, 16, such as at the boundaries between the cobalt features 22, 24 and the cap layers 26, 28 and/or the boundaries between the barrier/liner layer 18 and the cobalt features 22, 24. The thermal anneal causes reflow by increasing atomic mobility of the cobalt over the period of heating. Various approaches may be used that have different thermal budgets. The thermal anneal may comprise heating to a low temperature with rapid thermal annealing (RTA), such as heating to a temperature of 450° C. to 550° C. for a time of 1 minute to 10 minutes. Alternatively, the thermal anneal may comprise heating with a low temperature with laser spike annealing (LSA), such as heating to a temperature of 600° C. to 800° C. for a time in a range of 0.5 millisecond to 2.0 milliseconds, or less. Alternatively, the thermal anneal may comprise heating with a flash lamp, such as heating to a peak temperature of 600° C. and cooling to room temperature.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refers to a direction perpendicular to the horizontal, as just defined. The term “lateral” refers to a direction within the horizontal plane. Terms such as “above” and “below” are used to indicate positioning of elements or structures relative to each other as opposed to relative elevation.

A feature may be “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure comprising:
a dielectric layer including a top surface and an opening that penetrates from the top surface of the dielectric layer into the dielectric layer;
a feature in the opening, the feature comprised of cobalt and having a top surface;
a cap layer located on the top surface of the feature; and
a barrier/liner layer disposed between the feature and the opening in the dielectric layer, the barrier/liner layer separating the cap layer from the dielectric layer,
wherein the cap layer is comprised of a cobalt-containing alloy.

2. The structure of claim 1 wherein the cap layer is located inside the opening, and the cap layer has a top surface that is coplanar with the top surface of the dielectric layer.

3. The structure of claim 2 wherein the top surface of the feature is recessed relative to the top surface of the dielectric layer.

4. (canceled)

5. The structure of claim 1 wherein the cap layer is located inside the opening, and the cap layer has a top surface that is coplanar with the top surface of the dielectric layer.

6. The structure of claim 1 wherein the top surface of the feature is recessed relative to the top surface of the dielectric layer.

7. The structure of claim 1 wherein the cobalt-containing alloy includes cobalt and an element selected from the group consisting of nickel, ruthenium, niobium, tantalum, and manganese.

8. The structure of claim 1 wherein the barrier/liner layer and the cap layer cooperate to encapsulate the feature.

9. The structure of claim 8 wherein an outer edge of the cap layer has a contacting relationship with the barrier/liner layer.

10. The structure of claim 1 wherein the feature is a contact, and the opening is a contact opening.

11-20. (canceled)
